(19) United States
(12) Patent Application Publication
(10) Pub. No.: US 2018/0122670 A1
(43) Pub. Date: May 3, 2018

(54) REMOVABLE SUBSTRATE PLANE STRUCTURE RING

(71) Applicant: Varian Semiconductor Equipment Associates, Inc., Gloucester, MA (US)

(72) Inventors: Ernest E. Allen, Rockport, MA (US); Richard John Hertel, Boxford, MA (US); Jay R. Wallace, Danvers, MA (US); Keith A. Miller, Mountain View, CA (US)

(21) Appl. No.: 15/340,603

(22) Filed: Nov. 1, 2016

(51) Int. Cl. H01L 21/673; H01L 21/67

(52) U.S. Cl. CPC H01L 21/67353; H01L 21/67069

(57) ABSTRACT

An apparatus may include a platen to hold a substrate. A substrate plane structure may be disposed in front of the platen. The substrate plane structure has an opening therein. The apparatus may further include a removable structure disposed in the opening of the substrate plane structure. The removable structure may have an opening exposing a surface of the platen.

### BACKGROUND

### Field

This disclosure and described embodiments relate generally to the field of ion beam devices. More particularly, this disclosure and described embodiments relate to ion beam devices including a halo or substrate plane structure surrounding a substrate and a platen holding the substrate.

### Description of Related Art

In order to create desired surface features on a semiconductor wafer or other substrate, an ion beam of prescribed energy may be projected onto the surface of the substrate in a predetermined pattern to “etch” the desired features into the substrate. A platen may be employed to hold the substrate. During the etching process, the substrate can be mechanically driven or “scanned” in a direction transverse to an ion beam projected onto the substrate by an ion source. For example, if an ion beam is projected along a horizontal plane toward a vertically-oriented substrate, the substrate may be scanned in a vertical direction and/or in a lateral direction perpendicular to the projected ion beam. Thus, the entire surface of the substrate can be exposed to the ion beam.

Conventional apparatuses for projecting an ion beam on a substrate may include a halo or wafer plane structure surrounding the substrate and the platen. The halo or wafer plane structure may be used to mitigate ion beam exposure on the backside and edge of the substrate. Additionally, the wafer plane structure may be used to mitigate ion beam exposure on the platen and ion beam exposure to hardware and equipment near the platen.

The wafer plane structure used in conventional apparatuses for projecting an ion beam is generally a one-piece structure. Preventative maintenance of the one-piece structure design of conventional wafer plane structures generally requires the removal and possible replacement of the entire wafer plane structure. Therefore, the preventative maintenance of the one-piece structure design of conventional wafer plane structures may be costly. Moreover, the preventative maintenance of the one-piece structure design of conventional wafer plane structures may cause a lengthy operational downtime of associated apparatuses for projecting an ion beam.

With respect to these and other considerations the present improvements may be useful.

### SUMMARY

This Summary is provided to introduce a selection of concepts in a simplified form further described below in the Detailed Description. This Summary is not intended to identify key or essential features of the claimed subject matter, nor is this Summary intended as an aid in determining the scope of the claimed subject matter.

In one embodiment, an apparatus may include a platen to hold a substrate. A substrate plane structure may be disposed in front of the platen. The substrate plane structure has an opening therein. The apparatus may further include a removable structure disposed in the opening of the substrate plane structure. The removable structure may have an opening exposing a surface of the platen.

In another embodiment, an apparatus may include a platen to hold the substrate. A substrate plane structure may be disposed in front of the platen. The substrate plane structure may have an opening therein. A removable ring structure may be disposed in the opening of the substrate plane structure. The removable ring structure may have an opening exposing a surface of the platen.

In yet another embodiment, an apparatus may include a platen. A substrate may be coupled to the platen. The apparatus may further include a substrate plane structure disposed in front of the platen. The substrate plane structure may have an opening therein. A front surface of the substrate plane structure may be aligned with a front surface of the substrate. A removable ring structure may be disposed in the opening of the substrate plane structure. The removable ring structure may have an opening. The substrate may be disposed in the opening.

### BRIEF DESCRIPTION OF THE DRAWINGS

FIG. 1 shows a schematic block diagram of an ion beam etching system according to one embodiment of this disclosure;

FIG. 2 illustrates a frontal surface view of a substrate plane structure according to one embodiment of this disclosure;

FIG. 3 illustrates a cross-section view of the substrate plane structure, platen, substrate and removable structure, as viewed from the perspective of line I-I shown in FIG. 2, according to one embodiment of this disclosure;

FIG. 4 illustrates a cross-section view of the substrate plane structure, platen, substrate and removable structure, as viewed from the perspective of line I-I shown in FIG. 2, according to another embodiment of this disclosure.

### DETAILED DESCRIPTION

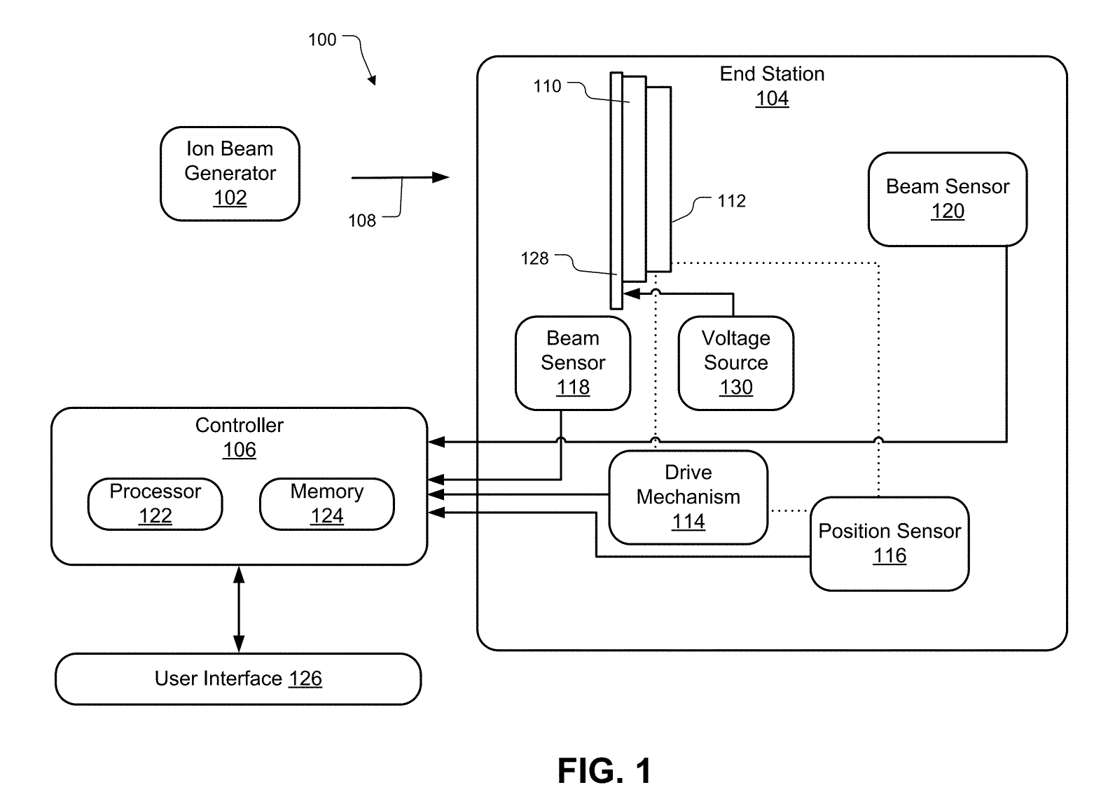

FIG. 1 shows a schematic block diagram of an ion beam etching system 100 according to one embodiment of this disclosure. The ion beam etching system 100 includes an ion beam generator 102, an end station 104, and a controller 106. The ion beam generator 102 generates an ion beam 108 and directs the ion beam 108 towards a front surface of a substrate 110. The ion beam 108 is distributed over the front surface of the substrate 110 by beam movement, substrate movement, or by any combination thereof.

The ion beam generator 102 can include various types of components and systems to generate the ion beam 108 having desired characteristics. The ion beam 108 may be a spot beam or a ribbon beam. The spot beam may have an irregular cross-sectional shape approximately circular in one instance. In one embodiment, the spot beam may be a fixed or stationary spot beam without a scanner. Alternatively, the spot beam may be scanned by a scanner for providing a scanned ion beam. The ribbon beam may have a large width/height aspect ratio and may be at least as wide as the substrate 110. The ion beam 108 can be any type of charged particle beam such as an energetic ion beam used to implant the substrate 110.

The end station 104 may support one or more substrates in the path of the ion beam 108 such that ions of the desired species are implanted into the substrate 110. The substrate 110 may be supported by a platen 112 and clamped to the platen 112 by known techniques such as electrostatic wafer clamping. The substrate 110 can take various physical shapes such as a common disk shape. The substrate 110 can be a workpiece such as a semiconductor wafer fabricated from any type of semiconductor material like silicon or any other material to be implanted and/or etched using the ion beam 108.

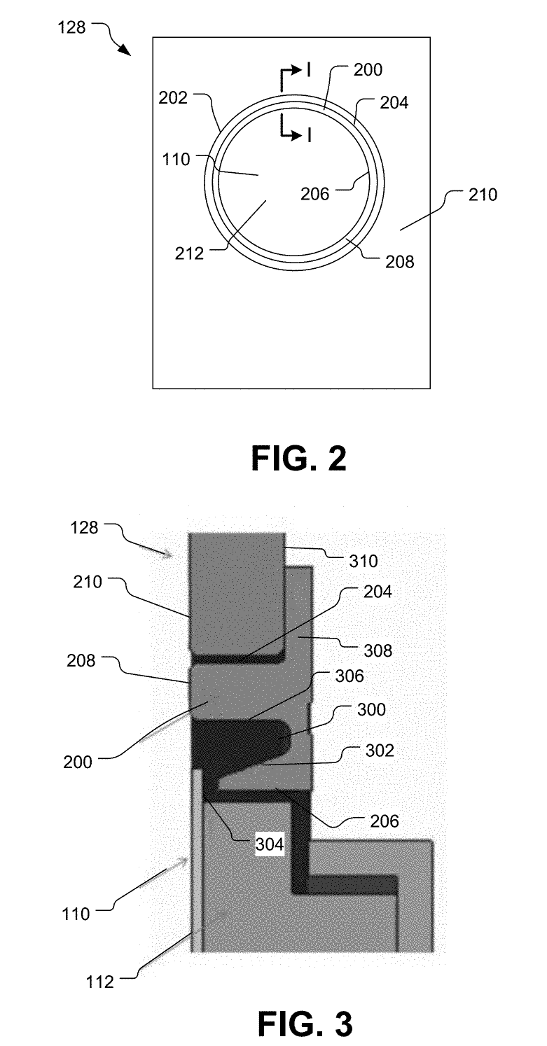

A halo or substrate plane structure 128 may be disposed in front of the substrate 110 and the platen 112. In one embodiment, the substrate plane structure 128 and a front surface of the substrate 110 form a common planar surface. The substrate plane structure 128 facilitates overscanning of the substrate 110. In particular, use of the substrate plane structure 128 reduces deposits or particles from accumulating on the edge and backside of the substrate 110 during the scanning of the substrate 110. Furthermore, use of the substrate plane structure 128 reduces deposits or particles from accumulating on the platen 112 and hardware and equipment in the vicinity of the platen 112. In one embodiment, a voltage source 130 may be coupled to a portion of the substrate plane structure 128. The voltage source 130 may be used to apply a charge to a portion of the substrate plane structure 128. In one embodiment, the voltage source 130 may be used to apply a voltage or charge to a removable structure 200 (see FIG. 2) associated with the substrate plane structure 128. Applying a charge to the removable structure 200 may further reduce deposits or particles that accumulate on the edge and backside of the substrate during the scanning of the substrate 110. Addition details of the substrate plane structure 128 will be provided in the following, with reference to FIGS. 2-4.

The end station 104 may include a drive system (not illustrated) to physically move the substrate 110 to and from the platen 112 from holding areas. The end station 104 may also include a drive mechanism 114 to drive the platen 112 and hence the substrate 110 in a desired way. The drive mechanism 114 may include servo drive motors, screw drive mechanisms, mechanical linkages, and any other components as are known in the art to drive the substrate 110 when attached to the platen 112.

The end station 104 may also include a position sensor 116 to provide a sensor signal representative of the position of the substrate 110 relative to the ion beam 108. The position sensor 116 may be coupled to the drive mechanism 114. Although illustrated as a separate component, the position sensor 116 may be part of other systems such as the drive mechanism 114. Furthermore, the position sensor 116 may be any type of position sensor known in the art such as a position-encoding device. The position signal from the position sensor 116 may be provided to the controller 106.

The end station 104 may also include various beam sensors to sense the beam current density of the ion beam 108 at various locations such as a beam sensor 118 upstream from the substrate 110 and a beam sensor 120 downstream from the substrate. As used herein, “upstream” and “downstream” are referenced in the direction of ion beam transport associated with the ion beam 108. Each beam sensor 118, 120 may contain a plurality of beam current sensors such as Faraday cups arranged to sense a beam current density distribution in a particular direction.

Those skilled in the art will recognize the ion beam etching system 100 may have additional components not shown in FIG. 1. For example, upstream of the substrate 110 there may be an extraction electrode to receive the ion beam from the ion beam generator 102 and accelerate the positively charged ions forming the beam. The ion beam etching system 100 may also include an analyzer magnet to receive the ion beam after positively charged ions have been extracted from the ion beam generator and accelerates and filters unwanted species from the beam. The ion beam etching system 100 may further include a mass slit to further limit the selection of species from the beam, electrostatic lenses to shape and focus the ion beam, and deceleration stages to manipulate the energy of the ion beam. The end station 104 may include other sensors such as a beam angle sensor, charging sensor, wafer position sensor, wafer temperature sensor, local gas pressure sensor, residual gas analyzer (RGA), optical emission spectroscopy (OES), ionized species sensors such as a time of flight (TOF) sensor to measure respective parameters.

The controller 106 may receive input data and instructions from any variety of systems and components of the ion beam etching system 100 and provide output signals to control the components of the system 100. The controller 106 can be or include a general-purpose computer or network of general-purpose computers programmed to perform desired input/output functions. The controller 106 may include a processor 122 and memory 124. The processor 122 may include one or more processors known in the art. The memory 124 may include one or more computer-readable medium providing program code or computer instructions for use by or in connection with a computer system or any instruction execution system. For the purposes of this description, a computer readable medium can be any apparatus that can contain, store, communicate, propagate, or transport the program for use by or in connection with the computer, instruction execution system, apparatus, or device. The computer-readable medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include a compact disk-read-only memory (CD-ROM), a compact disk-read/write (CD-R/W) and a digital video disc (DVD).

The controller 106 can also include other electronic circuitry or components, such as application specific integrated circuits, other hardwired or programmable electronic devices, discrete element circuits, etc. The controller 106 may also include communication devices.

A user interface system 126 may include, but not be limited to, devices such as touch screens, keyboards, user pointing devices, displays, printers, etc., to allow a user to input commands, data and/or to monitor the ion beam etching system 100 via the controller 106.

The controller 106 may be configured to allow a user to interact with the ion beam etching system 100. For example, the user can input a recipe for etching the substrate 110, view or modify a recipe automatically selected by the controller 106 for etching the substrate. The recipe embodies characteristics desired to be on the substrate 110. In particular, the recipe would embody values for process parameters the ion beam etching system 100 would use to produce a substrate with the desired characteristics. An illustrative but not exhaustive listing of process parameters includes vacuum chamber pressure, substrate temperature, ion beam species, energy, current, current density, ion to substrate angle, wafer scan velocity, beam scan velocity, end station pressure (or vacuum pumping speed), ion beam uniformity distribution. Additional parameters may include background pressure of one or more neutral gas species supplied by one or more individually adjustable gas flow controllers, the gas species used to generate plasma for plasma etching, plasma density, neutral density in the plasma, electron temperature and degree of electron confinement.

The controller 106 uses the values of the process parameters from the recipe to select values for ion beam parameters embodied in the ion beam 108 used to etch the substrate 110. An illustrative but not exhaustive listing of ion beam parameters the controller will set initial values for include ion beam intensity, ion beam current, angle that the ion beam 108 strikes the surface, and dose rate of ions in the ion beam 108. In one embodiment, the controller 106 selects initial values for these ion beam parameters from a historical database including a number of entries providing combinations of settings for these parameters as applied in past ion beam etchings. Typically, each entry has been compiled by receiving input data from various sources such as a recipe generator, a beam setup report, and an ion implant report.

The controller 106 also uses the values of the process parameters from the recipe to determine and control the application of atomic species applied by the ion beam generator 102 to the substrate 110 during the etching process. In one embodiment, the ion beam 108 generated by the ion beam generator 102 may be comprised of chemically inert species (Si+, Ar+, etc.) or additional chemical etching components (SiFx+, BF2, etc.). In another embodiment, the ion beam generator 102 can also introduce reactive species to aid in attaining uniform etching of the substrate 110. Typical reactive species can include HCL, Cl2, CO2, CO, O2, O3, CF4, NF3, NF2+ ions, BF2+ ions, F ions, F+ ions, Cl or Cl+ ions. The reactive species may also include UV light either with or without a reactive gas. In another embodiment, the ion beam generator 102 may also introduce neutral reactive species or reactive low energy ions.

In operation, after the substrate 110 has been loaded and clamped to the platen 112, the ion beam generator 102 applies the atomic species to the surface of the substrate. The atomic species are reactive to the surface of the substrate 110. After the atomic species have interacted with the surface of the substrate 110 for a predetermined time, then the ion beam generator 102 directs the ion beam 108 at the surface of the substrate 110. The ion beam 108 strikes the surface of the substrate 110 causing the atomic species to volatize and initiate the etch. In essence, the ion beam 108 controls the interaction the atomic species have with the surface of the substrate 110 and facilitates a more uniform etch of the substrate.

In order to ensure the ion beam 108 provides a uniform etch of the substrate 110, the controller 106 continually monitors the ion beam parameters (e.g., ion beam current, angle that the ion beam strikes the surface, and dose rate of ions in the ion beam). In particular, the controller receives measurements from beam sensors 118 and 120 and/or other sensors listed above. The received measurements take the form of signals indicative of ion beam properties the controller uses to correlate to beam parameters such as ion beam current, angle that the ion beam 108 strikes the surface of the substrate 110, density of the ion beam and dose rate of ions in the ion beam 108.

The controller 106 then takes the values for the ion beam parameters and determines the etch depth and etch rate of the ion beam with respect to the substrate 110. In particular, the controller determines etch depth and etch rate by using any well-known technique such as residual gas analysis (RGA), optical emission spectroscopy (OES) analysis of etch by products, surface analysis of the substrate by reflectometry, ellipsometry, interferometry, or other techniques. The etch depth and etch rate are used by the controller 106 to determine the uniformity of the etch. In particular, the local etch depth or local etch rate integrated in time provides a measurement of etch depth uniformity.

Although not shown in FIG. 1, the controller 106 can receive other measurements from sensors located within the end station 104. The other measurements may be used by the controller to control the uniformity of the etch. For example, controlling the temperature of the substrate 110 permits adjusting of the adsorption rate and time of the atomic species as well as the reaction rate through the desorption of the species. Typically, temperature control of the substrate 110 can be achieve through gas assisted cooling of the platen 112 or by cooling or heating the substrate 110. For example, through control of backside gas pressure and the platen 112 temperature, a radial temperature distribution facilitating a more uniform etch profile may be achieved.

FIG. 2 illustrates a frontal view of the substrate plane structure 128 according to one embodiment of this disclosure. As is illustrated, the substrate plane structure 128 includes a removable structure 200 disposed in an opening 202 of the substrate plane structure 128. In one embodiment, the removable structure 200 is a removable ring structure. In the figure, the substrate 110 is illustrated as being disposed in the opening 202. The platen 112 holding the substrate 110 is behind the substrate 110. When the substrate 110 is not being held by the platen 112, the platen 112 is generally exposed in the opening 202.

The removable structure 200 has an outside edge surface 204 and an inside edge surface 206. A circumference of the inside edge surface 206 is greater than a circumference of the platen 112. Furthermore, in one embodiment, the removable structure 200 has an exterior surface 208 aligned with a front surface 210 of the substrate plane structure 128. Furthermore, in one embodiment, a front surface 212 of the substrate 110 may be aligned with the front surface 210 of the substrate plane structure 128 and the exterior surface 208 of the removable structure 200. Therefore, in one embodiment, the exterior surface 208 of the removable structure 200, the front surface 210 of the substrate plane structure 128, and the front surface 212 of the substrate 110 form a planar surface. In another embodiment, the exterior surface 208 is not aligned with the front surface 210 of the substrate plane structure 128 and/or the front surface 212 of the substrate 110.

FIG. 3 illustrates a cross-section view of the substrate plane structure 128, platen 112, substrate 110 and the removable structure 200, as viewed from the perspective of line I-I shown in FIG. 2, according to one embodiment of this disclosure. The cross-section view illustrated in FIG. 3 shows the removable structure 200 includes a groove 300. The groove 300 may be formed in at least a portion of a circumference of the removable structure 200. In one embodiment, the groove 300 is formed in the entire circumference of the removable structure 200. The groove 300 may include an angled surface 302 functional to direct the particles associated with the ion beam 108 away from a backside 304 of the substrate 110. Moreover, the angled surface 302 is functional to direct particles associated with the ion beam 108 away from the platen 112. In one embodiment, particles associated with the ion beam 108 may be directed by the angled surface 302 toward a surface 306 associated with the groove 300. The groove 300 may be formed having a shallower or deeper depth than shown in FIG. 3. Furthermore, while the surface 306 is illustrated as being straight, the surface 306 may alternatively be formed at an angle similar to the angled surface 302.

As is further illustrated in FIG. 3, the removable structure 200 includes a ledge 308. The ledge 308 may be in contact with a backside 310 of the substrate plane structure 128. In one embodiment, the ledge 308 is removably press fit against the substrate plane structure 128, on the backside 310 of the substrate plane structure 128.

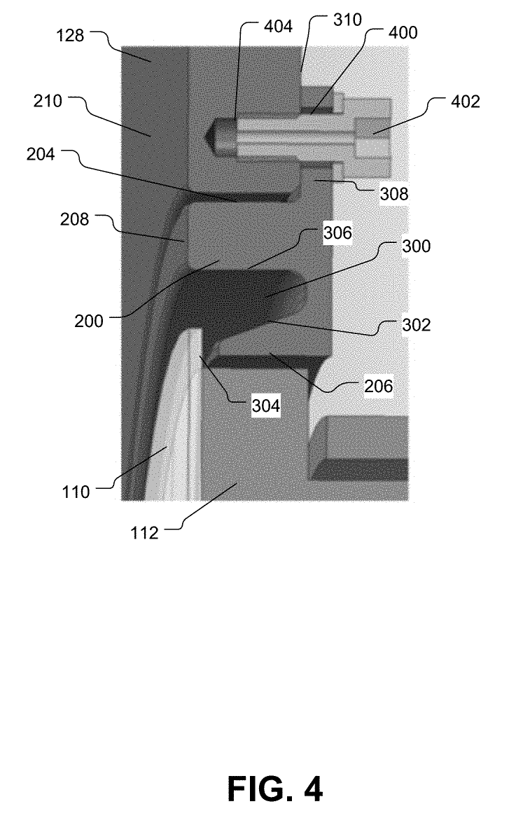

FIG. 4 illustrates a cross-section view of the substrate plane structure 128, platen 112, substrate 110 and the removable structure 200, as viewed from the perspective of line I-I shown in FIG. 2, according to another embodiment of this disclosure. FIG. 4 illustrates the removable structure 200 may include one or more through holes 400. In one embodiment, a plurality of through holes 400 are disposed in the ledge 308. The plurality of through holes 400 may receive a retainer element 402, such as a fastener, screw, or the like. Each of the retainer elements 402 may be received by a hole 404 in the substrate plane structure 128. Therefore, the substrate plane structure 128 may include a plurality of the holes 404. In another embodiment, the holes 404 may be through holes so that the retainer elements 402 may be inserted from the front surface 210 of the substrate plane structure 128 and retainably attached to the ledge 308 using a nut, fastener or threads.

The substrate plane structure having a removable ring is advantageously straightforward to maintain. Specifically, advantageously, rather than removing the entire substrate plane structure when preventive maintenance is required, it may be possible to simply remove the removable ring to complete the required preventative maintenance. Furthermore, because the substrate plane structure and the removable ring pieces advantageously provide a modular unit, the costs associated with maintaining and replacing the modular unit may be advantageously reduced compared to maintaining and replacing conventional substrate plane structures formed as one contiguous unit. In addition, advantageously, removable rings may be made from different materials compared to the remainder of the substrate plan structure. For example, use of particular material types for the removable rings may advantageously mitigate accumulation of deposits and particles on the edge of the wafer. On the other hand, use of other particular material types of the removable rings may advantageously aid in controlling an electrical field of the ion beam.

While exemplary ion implanter devices and methods are disclosed, it will be understood by those skilled in the art that various changes may be made and equivalents may be substituted without departing from the spirit and scope of the claims of the application. Other modifications may be made to adapt a particular situation or material to the teachings disclosed above without departing from the scope of the claims. Therefore, the claims should not be construed as being limited to any one of the particular embodiments disclosed, but to any embodiments that fall within the scope of the claims.

We claim:

1. An apparatus, comprising:
a platen to hold a substrate;
a substrate plane structure disposed in front of the platen, the substrate plane structure having an opening therein; and
a removable structure disposed in the opening of the substrate plane structure, the removable structure having an opening exposing a surface of the platen.

2. The apparatus according to claim 1, wherein the removable structure has an inside edge surface and an outside edge surface, the inside edge surface having a circumference greater than a circumference of the platen.

3. The apparatus according to claim 1, wherein the removable structure is removably affixed to a backside of the substrate plane structure using one or more removable retainer elements.

4. The apparatus according to claim 1, wherein the removable structure includes a ledge in contact with a backside of the substrate plane structure.

5. The apparatus according to claim 4, wherein the ledge includes one or more through holes aligned with one or more holes in the backside of the substrate plane structure, at least one removable retainer element is disposed in the one or more through holes and the one or more holes in the backside of the substrate plane structure to removably affix the removable structure to the substrate plane structure.

6. The apparatus according to claim 1, wherein the removable structure is a removable ring structure.

7. The apparatus according to claim 6, wherein the removable ring structure further includes a groove formed in at least a portion of a circumference of the removable ring structure.

8. The apparatus according to claim 1, further comprising a voltage source coupled to the removable structure, the voltage source to apply a voltage to the removable structure.

9. An apparatus, comprising:
a platen to hold a substrate;
a substrate plane structure disposed in front of the platen, the substrate plane structure having an opening therein; and
a removable ring structure disposed in the opening of the substrate plane structure, the removable ring structure having an opening exposing a surface of the platen.

10. The apparatus according to claim 9, wherein the removable ring structure has an inside edge surface and an outside edge surface, the inside edge surface having a circumference greater than a circumference of the platen.

11. The apparatus according to claim 9, wherein the removable ring structure is removably affixed to a backside of the substrate plane structure using one or more removable retainer elements.

12. The apparatus according to claim 9, wherein the removable ring structure includes a ledge in contact with a backside of the substrate plane structure.

13. The apparatus according to claim 12, wherein the ledge includes one or more through holes aligned with one or more holes in the backside of the substrate plane structure, at least one removable retainer element is disposed in the one or more through holes and the one or more holes in the backside of the substrate plane structure to removably affix the removable ring structure to the substrate plane structure.

14. The apparatus according to claim 9, wherein the removable ring structure further includes a groove formed in at least a portion of a circumference of the removable ring structure.

15. The apparatus according to claim 14, wherein the groove is formed in an entire circumference of the removable ring structure.

16. An apparatus, comprising:
a platen;
a substrate coupled to the platen;
a substrate plane structure disposed in front of the platen and having an opening therein, the substrate plane structure having a front surface aligned with a front surface of the substrate; and
a removable ring structure disposed in the opening of the substrate plane structure, the removable ring structure having an opening in which the substrate is disposed.

17. The apparatus according to claim 16, wherein the removable ring structure has an inside edge surface and an outside edge surface, the inside edge surface having a circumference greater than a circumference of the platen.

18. The apparatus according to claim 16, wherein the removable ring structure is removably affixed to a backside of the substrate plane structure using one or more removable retainer elements.

19. The apparatus according to claim 16, wherein the removable ring structure includes a ledge in contact with a backside of the substrate plane structure.

20. The apparatus according to claim 16, wherein the ledge includes one or more through holes aligned with one or more holes in the backside of the substrate plane structure, at least one removable retainer element is disposed in the one or more through holes and the one or more holes in the backside of the substrate plane structure to removably affix the removable ring structure to the substrate plane structure.
